(19) United States
(12) Patent Application Publication
(10) Pub. No.: US 2025/0140687 A1
(43) Pub. Date: May 1, 2025

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Wen-Ling CHANG, Miaoli County (TW); Chi-Hao CHANG, Taoyuan City (TW); Hsiang-Ku SHEN, Hsinchu City (TW); Dian-Hau CHEN, Hsinchu (TW)

(73) Assignee: Taiwan Semiconductor Manufacturing Company, Ltd., Hsinchu (TW)

(21) Appl. No.: 18/493,948

(22) Filed: Oct. 25, 2023

(51) Int. Cl. H01L 23/528; H01L 21/768; H01L 23/522

(52) U.S. Cl. CPC H01L 23/5283; H01L 21/76843; H01L 21/76898; H01L 23/5226

(57) ABSTRACT

A method for forming a semiconductor device structure is provided. The method includes forming an interconnect structure over a substrate. The method further includes forming a passivation layer over the interconnect structure. The method further includes forming a conductive structure over the passivation layer, wherein the conductive structure includes a surrounding portion over the passivation layer, and a concave portion surrounded by the surrounding portion. A height of the surrounding portion is greater than a height of the concave portion calculated from a top surface of the passivation layer. The method further includes forming a liner over the conductive structure, wherein an oxygen-to-silicon ratio of the liner is lower than about 1.8.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1S are cross-sectional views of various stages of a process for forming a semiconductor device structure, in accordance with some embodiments.

FIG. 2 is a schematic view of a semiconductor device structure, in accordance with some embodiments of the present disclosure.

FIG. 3 is a schematic view of a semiconductor device structure, in accordance with some embodiments of the present disclosure.

FIG. 4 is a schematic view of a semiconductor device structure, in accordance with some embodiments of the present disclosure.

FIG. 5 is a schematic view of a semiconductor device structure, in accordance with some embodiments of the present disclosure.

FIG. 6 is a schematic view of a semiconductor device structure, in accordance with some embodiments of the present disclosure.

FIG. 7 is a schematic view of a semiconductor device structure, in accordance with some embodiments of the present disclosure.

FIG. 8 is a schematic view of a semiconductor device structure, in accordance with some embodiments of the present disclosure.

FIG. 9 is a schematic view of a semiconductor device structure, in accordance with some embodiments of the present disclosure.

FIG. 10 shows a semiconductor package structure formed with the semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

The term “about” as used herein indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

Furthermore, the phrase “in a range between a first value and a second value” or “in a range from a first value to a second value” indicates that the range includes the first value, the second value, and other values between them.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100%. Furthermore, terms such as “substantially parallel” or “substantially perpendicular” are to be interpreted as not to exclude insignificant deviation from the specified arrangement and may include for example deviations of up to 10°. The word “substantially” does not exclude “completely” e.g. a composition which is “substantially free” from Y may be completely free from Y.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

System-on-Integrated-Chips (SoIC) semiconductor device structures and methods for forming the same are provided in some embodiments of the present disclosure. The semiconductor device structure includes a silicon-rich liner with modified mechanical strength to inhibit crack propagation, which enhances yield and reliability of the semiconductor device structure.

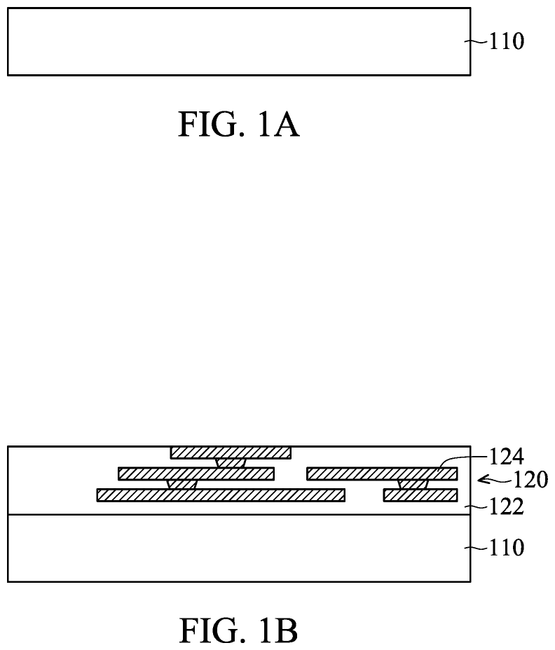

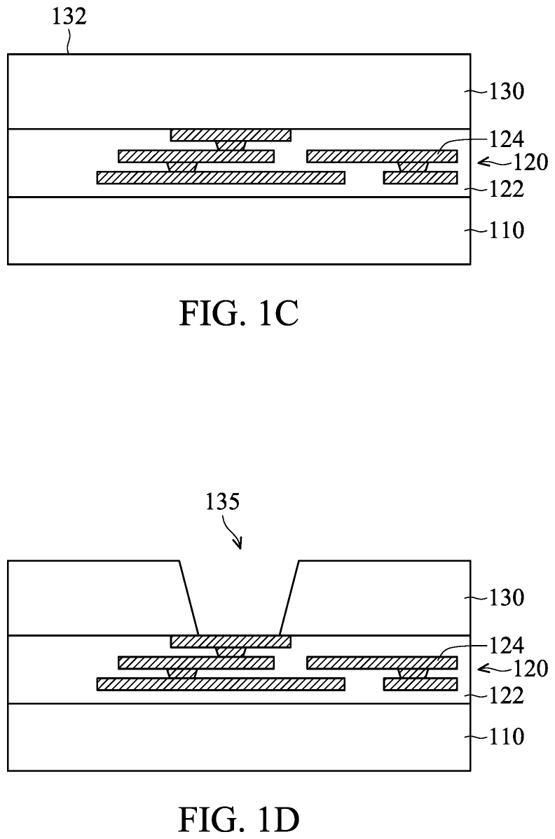

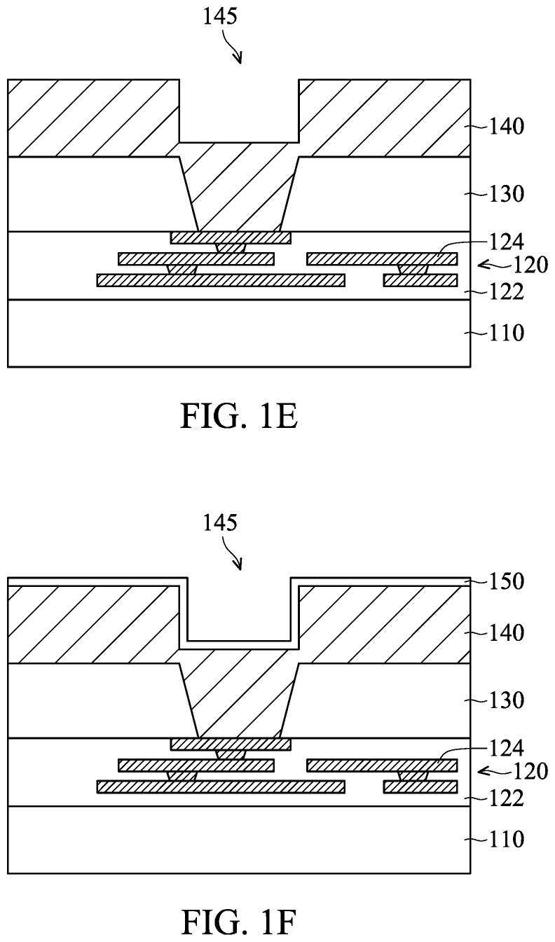

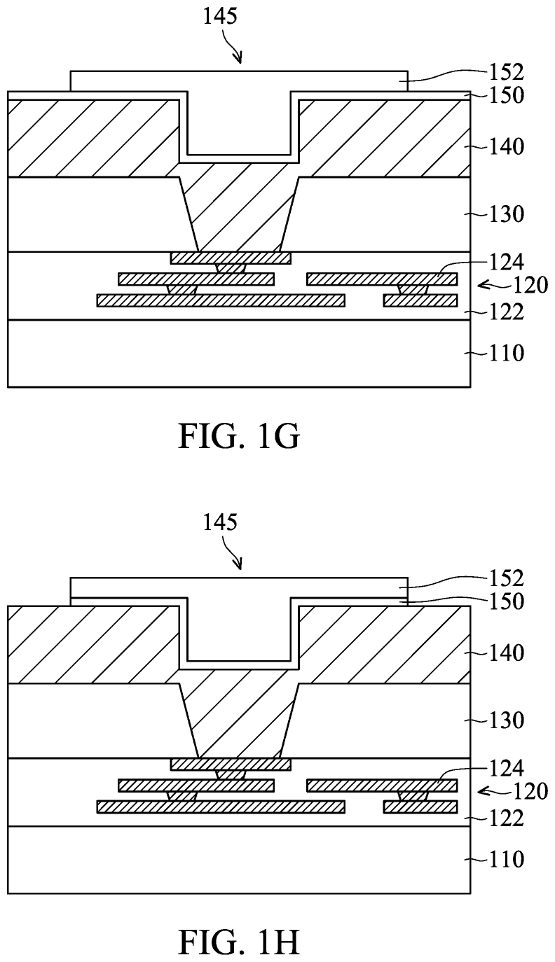

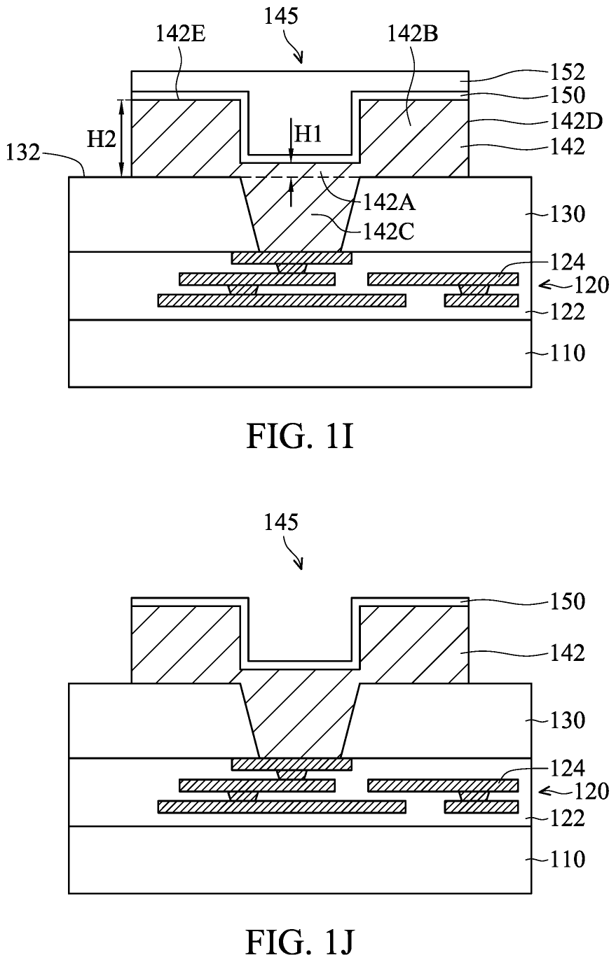

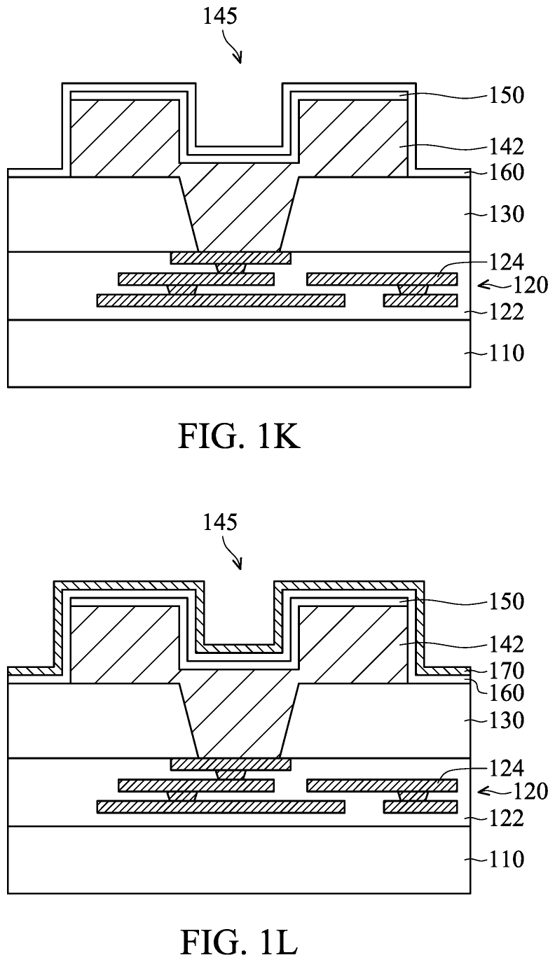

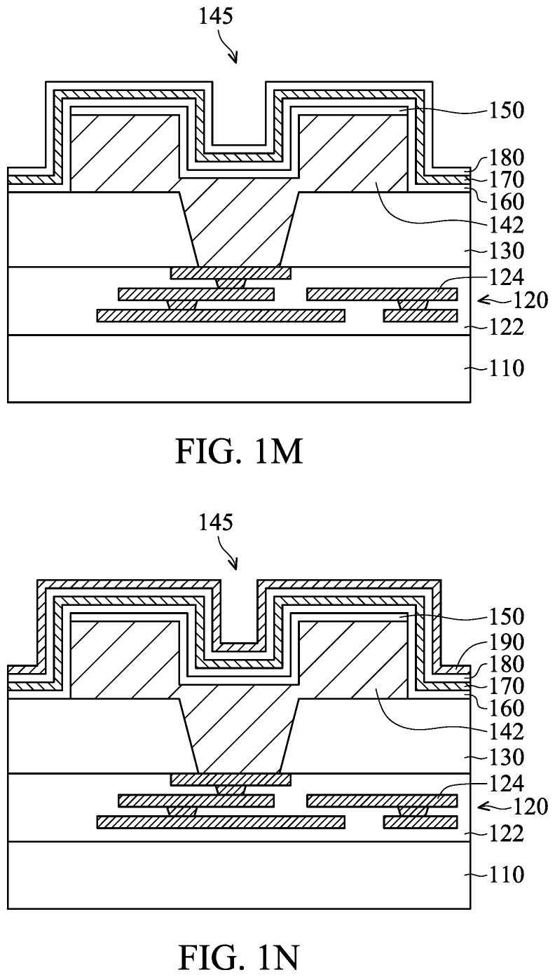

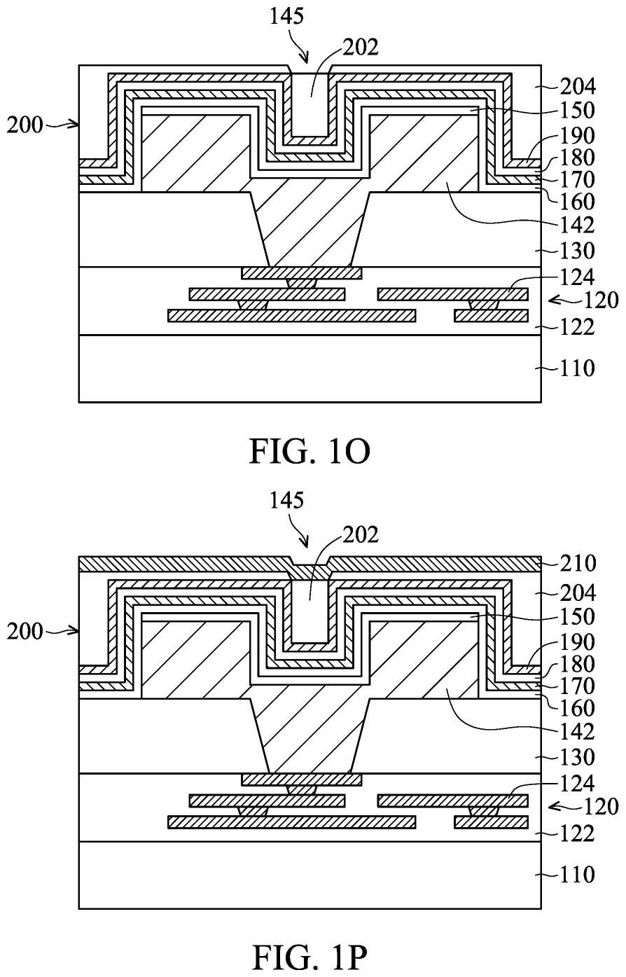

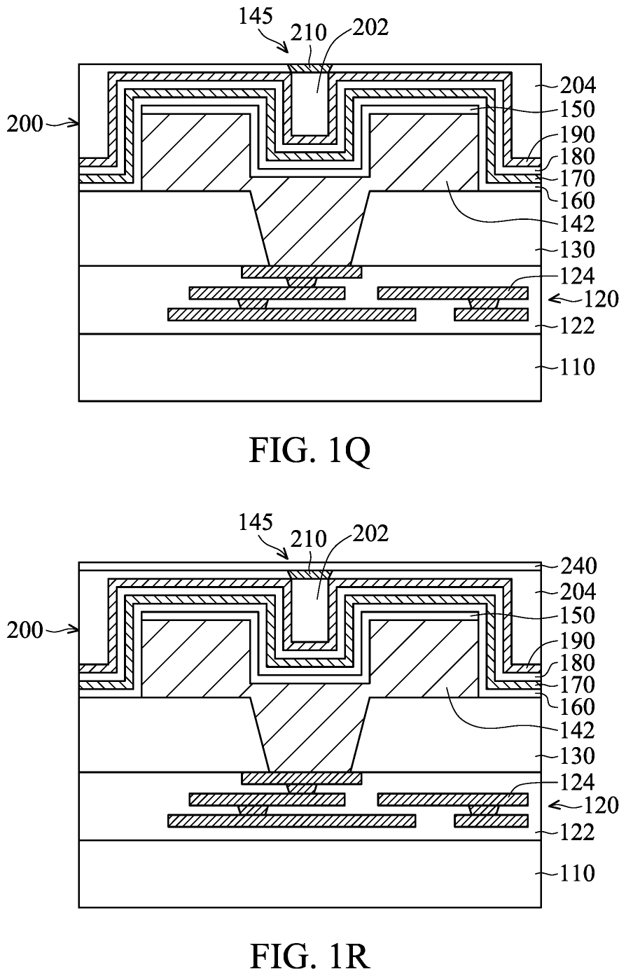

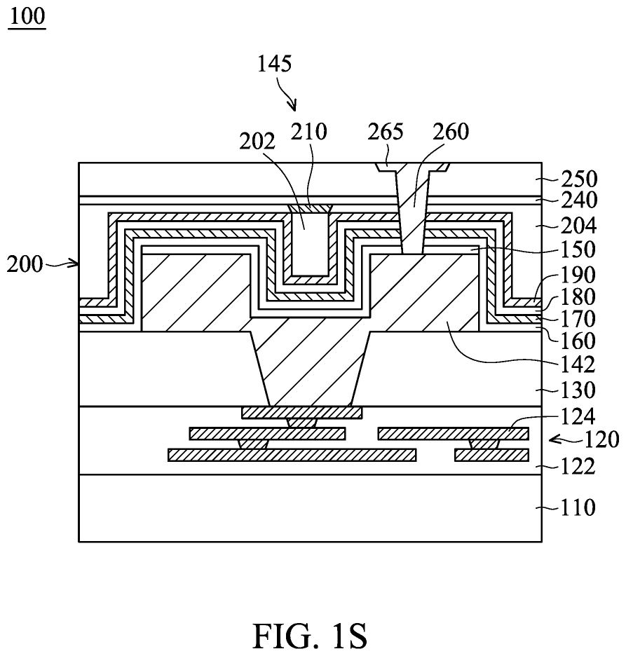

FIGS. 1A-1S are cross-sectional views of various stages of a process for forming a semiconductor device structure 100, in accordance with some embodiments. As shown in FIG. 1A, a substrate 110 is provided, in accordance with some embodiments. The substrate 110 includes, for example, a semiconductor substrate. The substrate 110 includes, for example, a semiconductor wafer (such as a silicon wafer) or a portion of a semiconductor wafer.

In some embodiments, the substrate 110 is made of an elementary semiconductor material including silicon or germanium in a single crystal structure, a polycrystal structure, or an amorphous structure. In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements (not shown). In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIG. 1B, an interconnect structure 120 is formed over the substrate 110, in accordance with some embodiments. The interconnect structure 120 includes a dielectric structure 122 and conductive structures 124 formed in the dielectric structure 122, in accordance with some embodiments. In some embodiments, the dielectric structure 122 includes wiring layers and vias electrically connected between different wiring layers and between the wiring layer and the aforementioned device elements, in accordance with some embodiments.

The dielectric structure 122 is made of an oxide-containing material (e.g. silicon oxide or undoped silicate glass) or another suitable insulating material, in accordance with some embodiments. The conductive structures 124 are made of conductive materials such as metal (e.g., aluminum, copper, gold, silver, tungsten or the like) or alloys thereof, in accordance with some embodiments.

As shown in FIG. 1C, a passivation layer 130 is formed over the interconnect structure 120, in accordance with some embodiments. The passivation layer 130 is made of a dielectric material, such as silicon nitride, silicon oxynitride, silicon oxide, or undoped silicate glass (USG), in accordance with some embodiments. The passivation layer 130 is formed using a deposition process (e.g., a chemical vapor deposition process or a physical vapor deposition process), in accordance with some embodiments.

As shown in FIG. 1D, portions of the passivation layer 130 are removed to form a through hole 135, in accordance with some embodiments. The through hole 135 passes through the passivation layer 130 to expose a portion of the conductive structure 124, in accordance with some embodiments. The removal process includes a photolithography process and an etching process, such as a dry etching process, in accordance with some embodiments.

As shown in FIG. 1E, a conductive layer 140 is conformally formed over the passivation layer 130 and in the through holes 135, in accordance with some embodiments. The conductive layer 140 is connected to the conductive structure 124, in accordance with some embodiments. A recess 145 is formed on the conductive layer 140 and corresponding to the position of the through hole 135, such as overlap each other in a direction perpendicular to the substrate 110, in accordance with some embodiments.

The conductive layer 140 is made of a conductive material, such as metal (e.g., aluminum) or alloys (e.g., aluminum-copper alloy) thereof, in accordance with some embodiments. The conductive layer 140 is formed using a deposition process such as a physical vapor deposition (PVD) process or a chemical vapor deposition (CVD) process, in accordance with some embodiments.

As shown in FIG. 1F, a dielectric layer 150 is formed over the conductive layer 140, in accordance with some embodiments. The dielectric layer 150 conformally covers the conductive layer 140, in accordance with some embodiments. The dielectric layer 150 is partially formed in the recess 145 of the conductive layer 140, in accordance with some embodiments.

The dielectric layer 150 is made of a dielectric material, such as nitrides (e.g., silicon oxynitride), in accordance with some embodiments. The dielectric layer 150 is formed using a deposition process such as a chemical vapor deposition (CVD) process or a physical vapor deposition (PVD) process, in accordance with some embodiments.

As shown in FIG. 1G, a mask layer 152 is formed over the dielectric layer 150 and partially covers the top surface of the dielectric layer 150, in accordance with some embodiments. The dielectric layer 150 is partially exposed from the mask layer 152, in accordance with some embodiments. The mask layer 152 is made of a polymer material such as a photoresist material, in accordance with some embodiments.

As shown in FIG. 1H, portions of the dielectric layer 150 exposed from the mask layer 152 are removed, in accordance with some embodiments. The removal process includes an etching process such as a dry etching process, in accordance with some embodiments. Portions of the conductive layer 140 are exposed from the dielectric layer 150 after the removal process, in accordance with some embodiments.

As shown in FIG. 1I, portions of the conductive layer 140 not covered by the mask layer 152 and the dielectric layer 150 are removed, in accordance with some embodiments. The remaining conductive layer 140 may act as conductive lines or conductive pads, and may be referred to as a conductive structure 142, in accordance with some embodiments. A side surface 142D of the conductive structure 142 is exposed from the mask layer 152 and the dielectric layer 150 after the removal process, in accordance with some embodiments. The removal process includes an etching process such as a dry etching process, in accordance with some embodiments.

In some embodiments, the conductive structure 142 includes a concave portion 142A, a surrounding portion 142B, and a via portion 142C. The concave portion 142A is surrounded by the surrounding portion 142B and over the via portion 142C, in accordance with some embodiments. In some embodiments, the via portion 142C extends into the passivation layer 130 and connects to the conductive structures 124. In some embodiments, the via portion 142C is below the concave portion 142A and formed in the through hole 135 (FIG. 1D). In some embodiments, the concave portion 142A overlaps the through hole 135. In some embodiments, the surrounding portion 142B is non-overlapping the via portion 142C and covers a top surface of the passivation layer 130. In some embodiments, the dielectric layer 150 extends into the conductive structure 142, such as extended into and partially surrounded by the surrounding portion 142B.

When calculated from the top surface 132 of the passivation layer 130, the concave portion 142A has a height of H1, the surrounding portion 142B has a height of H2, and H2>H1, in accordance with some embodiments. The concave portion 142A is concave from the top surface 142E of the conductive structure 142, in accordance with some embodiments. In some embodiments, the top surface 142E faces the dielectric layer 150.

As shown in FIG. 1J, the mask layer 152 is removed, in accordance with some embodiments. The removal process includes an etching process such as a dry etching process, in accordance with some embodiments. The dielectric layer 150 remains over the conductive structure 142, in accordance with some embodiments. The dielectric layer 150 is used as an etch stop layer in subsequent processes, in accordance with some embodiments.

As shown in FIG. 1K, a passivation layer 160 is formed over the passivation layer 130 and the dielectric layer 150, in accordance with some embodiments. The passivation layer covers the side surface 142D of the conductive structure 142, in accordance with some embodiments. The passivation layer 160 is made of a dielectric material, such as silicon nitride, silicon oxynitride, silicon oxide, or undoped silicate glass (USG), in accordance with some embodiments. The passivation layer 160 is formed using a deposition process (e.g., a chemical vapor deposition process or a physical vapor deposition process), in accordance with some embodiments.

As shown in FIG. 1L, a dielectric layer 170 is formed over the passivation layer 160, in accordance with some embodiments. The dielectric layer 170 is made of nitrides such as silicon nitride or the like, in accordance with some embodiments. The dielectric layer 170 is formed using a deposition process such as a chemical vapor deposition (CVD) process or a physical vapor deposition (PVD) process, in accordance with some embodiments.

As shown in FIG. 1M, a passivation layer 180 is formed over the dielectric layer 170, in accordance with some embodiments. The passivation layer 180 is made of a dielectric material, such as silicon nitride, silicon oxynitride, silicon oxide, or undoped silicate glass (USG), in accordance with some embodiments. The passivation layer 180 is formed using a deposition process (e.g., a chemical vapor deposition process or a physical vapor deposition process), in accordance with some embodiments.

As shown in FIG. 1N, a liner 190 is formed over the passivation layer 180, in accordance with some embodiments. In some embodiments, the liner 190 is partially surrounded by the conductive structure 142. The liner 190 is made of a dielectric material, such as silicon oxide.

Since the conductive structure 142 has a concave portion 142A, crack may propagate because of stress concentration. In some embodiments, the oxygen-to-silicon ratio of the liner 190 is less than 1.8, such as between about 1.5 and about 1.8. In such embodiment, the refractive index (RI) of the liner 190 is between about 1.6 and about 1.7. In some embodiments, the refractive index the liner 190 is less than 1.8. In some embodiments, the thickness of the liner 190 is between about 50 and about 150 nm. Therefore, the density and hardness of the liner 190 can be adjusted to prevent crack propagation, which increases the yield.

As shown in FIG. 1O, a buffer layer 200 is formed over the liner 190 and in the recesses 145, in accordance with some embodiments. The buffer layer 200 is made of oxides such as silicon oxide or the like, in accordance with some embodiments. In some embodiments, the oxide layer includes a first portion 202 in the recess 145 and a second portion 204 outside the recess 145. In some embodiments, the first portion 202 and the second portion 204 are discontinuous. In some embodiments, the thickness of the first portion 202 is greater than the thickness of the dielectric layer 150, the passivation layer 160, the dielectric layer 170, the passivation layer 180, or the liner 190. In some embodiments, the thickness of the first portion 202 is greater than 1.5 μm, in accordance with some embodiments of the present disclosure. In some embodiments, the first portion 202 of the buffer layer 200 is surrounded by the surrounding portion 142B.

The buffer layer 200 is formed using a deposition process such as a chemical vapor deposition (CVD) process, in accordance with some embodiments. The chemical vapor deposition process includes a High-Density Plasma Chemical Vapor Deposition (HDP-CVD) process, in accordance with some embodiments.

As shown in FIG. 1P, a buffer layer 210 is formed over the buffer layer 200, in accordance with some embodiments. The buffer layer 210 is in direct contact with the buffer layer 200, in accordance with some embodiments. The buffer layer 210 is made of undoped silicate glass, silicon oxide, or the like, in accordance with some embodiments. The buffer layer 210 is formed using a deposition process such as a chemical vapor deposition (CVD) process or a physical vapor deposition (PVD) process, in accordance with some embodiments.

In some embodiments, the material of the buffer layer 200 and the buffer layer 210 may be different. For example, the oxygen content of the buffer layer 200 may be less than the oxygen content of the buffer layer 210, which increases the hardness of the buffer layer 200 to prevent crack propagation, in accordance with some embodiments.

As shown in FIG. 1Q, top portions of the buffer layer 210 are removed, in accordance with some embodiments. The removal process partially exposes the buffer layer 200 underneath the buffer layer, in accordance with some embodiments. In some embodiments, some of the buffer layer 210 remains, such as above the concave portion 142A, in accordance with some embodiments. The removal process includes a planarization process such as a chemical mechanical polishing process, in accordance with some embodiments.

As shown in FIG. 1R, a nitride layer 240 is formed over the buffer layers 200 and 210, in accordance with some embodiments. The nitride layer 240 has a flat top surface, in accordance with some embodiments. The nitride layer 240 is used to prevent moisture from being absorbed by the components underneath, in accordance with some embodiments.

The nitride layer 240 is made of nitrides such as silicon nitride or the like, in accordance with some embodiments. The nitride layer 240 is formed using a deposition process such as a chemical vapor deposition (CVD) process or a physical vapor deposition (PVD) process, in accordance with some embodiments.

As shown in FIG. 1S, an insulating layer 250 is formed over the nitride layer 240, in accordance with some embodiments of the present disclosure. In some embodiments, the insulating layer 250 may be referred to as an intermetal dielectric (IMD) layer and may include silicon oxide or a low-k dielectric material whose k-value (dielectric constant) is smaller than that of silicon oxide, which is about 3.9. In some embodiments, the low-k dielectric material includes a porous organosilicate thin film such as SiOCH, tetraethylorthosilicate (TEOS) oxide, undoped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, silicon carbon nitride (SiCN), silicon oxycarbide (SiOCN), spin-on silicon based polymeric dielectrics, or combinations thereof.

A via 260 is formed to penetrate the dielectric layer 150, the passivation layer 160, the dielectric layer 170, the passivation layer 180, the liner 190, the buffer layer 200, the buffer layer 210, the nitride layer 240, and the insulating layer 250, and a bonding pad 265 is formed in the insulating layer 250 and above the via 260, in accordance with some embodiments. The via 260 is connected to the surrounding portion 142B of the conductive structure 142, such as landing on the conductive structure 142, in accordance with some embodiments. Therefore, a semiconductor device structure 100 is formed, in accordance with some embodiments of the present disclosure.

The via 260 and the bonding pad 265 are made of a conductive material, such as metal (e.g., aluminum) or alloys (e.g., aluminum-copper alloy) thereof, in accordance with some embodiments. The via 260 and the bonding pad 265 is formed using a deposition process such as a physical vapor deposition (PVD) process or a chemical vapor deposition (CVD) process, in accordance with some embodiments.

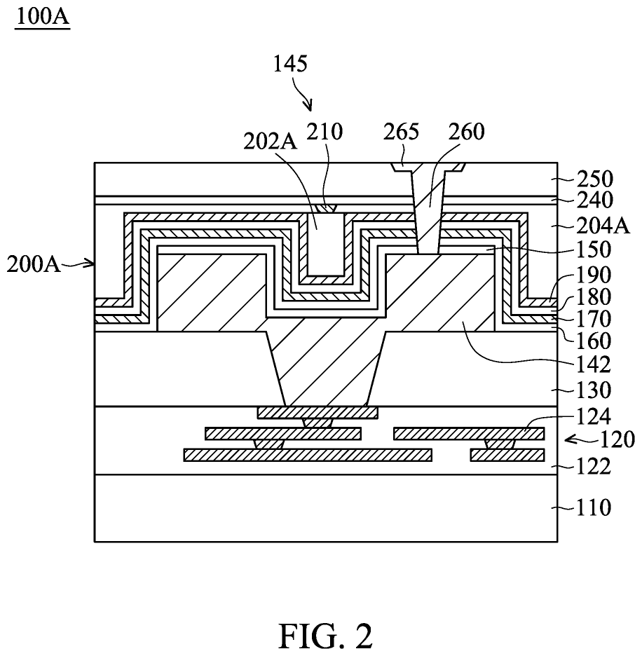

FIG. 2 is a schematic view of a semiconductor device structure 100A, in accordance with some embodiments of the present disclosure. Elements with similar reference numbers are not described again for simplicity. As shown in FIG. 2, the semiconductor device structure 100A has a buffer layer 200A, the buffer layer 200A has a first portion 202A in the recess 145 and a second portion 204A outside the recess 145 in accordance with some embodiments of the present disclosure. The first portion 202A and the second portion 204A are continuously formed over the conductive structure 142, in accordance with some embodiments of the present disclosure.

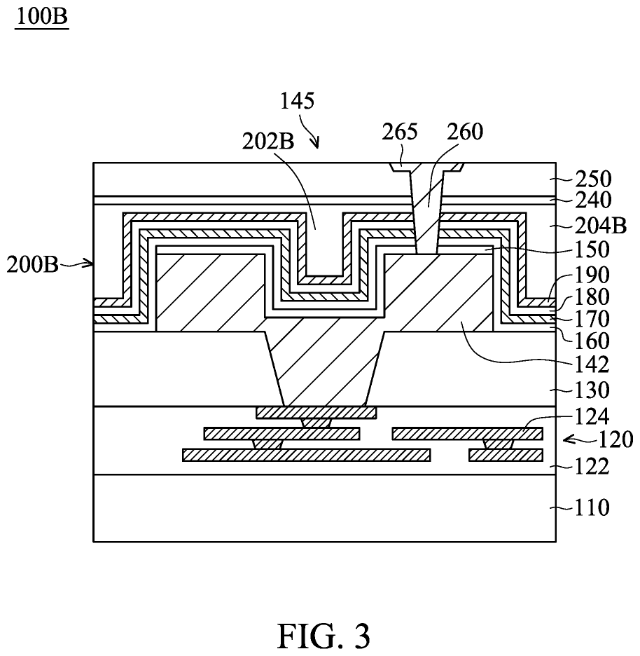

FIG. 3 is a schematic view of a semiconductor device structure 100B, in accordance with some embodiments of the present disclosure. Elements with similar reference numbers are not described again for simplicity. As shown in FIG. 3, the semiconductor device structure 100B has a buffer layer 200B that continuously extends across the semiconductor device structure 100B, and it has a flat top surface, in accordance with some embodiments of the present disclosure.

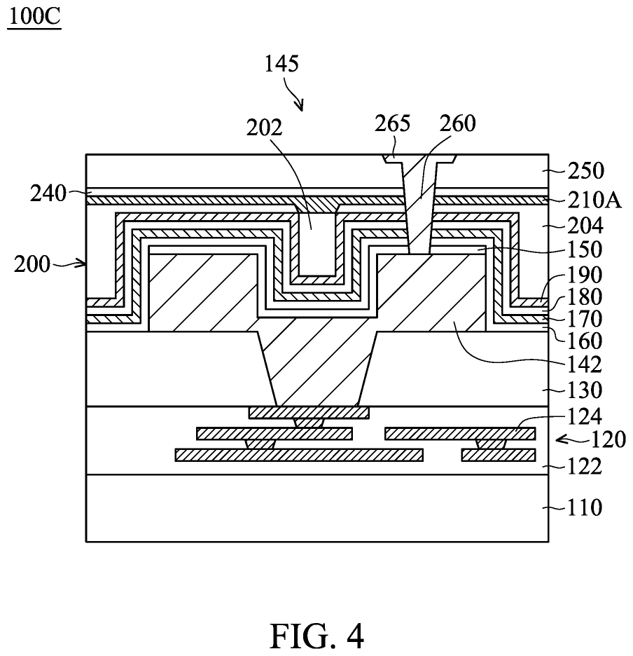

FIG. 4 is a schematic view of a semiconductor device structure 100C, in accordance with some embodiments of the present disclosure. Elements with similar reference numbers are not described again for simplicity. As shown in FIG. 4, the semiconductor device structure 100C has a buffer layer 210A over the buffer layer 200, in accordance with some embodiments of the present disclosure. The buffer layer 210A continuously extends across the semiconductor device structure 100C, and it has a flat top surface, in accordance with some embodiments of the present disclosure.

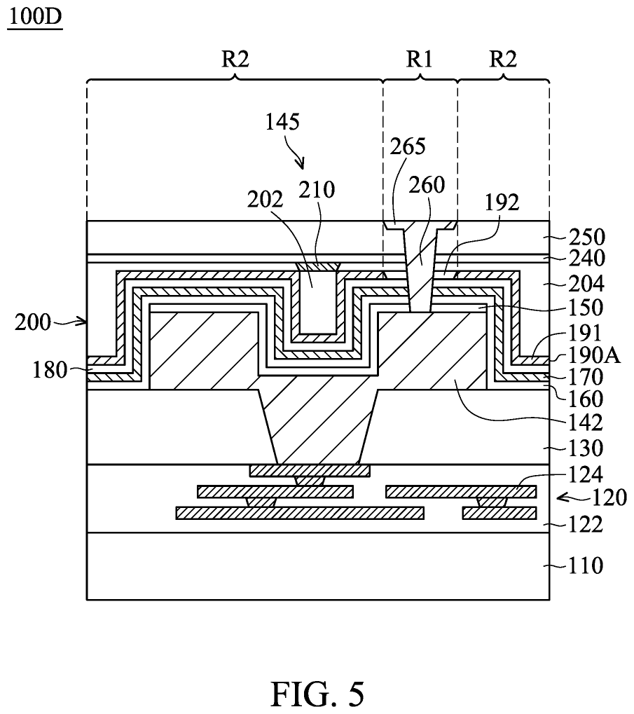

FIG. 5 is a schematic view of a semiconductor device structure 100D, in accordance with some embodiments of the present disclosure. Elements with similar reference numbers are not described again for simplicity. As shown in FIG. 5, the semiconductor device structure 100D has a region R1 adjacent to the via 260 and a region R2 spaced apart from the via 260 by the region R1, in accordance with some embodiments of the present disclosure. In some embodiments, the region R1 is surrounded by the region R2.

The semiconductor device structure 100D has a liner 190A with a liner portion 191 in the region R1 and a liner portion 192 in the region R2, in accordance with some embodiments of the present disclosure. The liner portion 191 and the liner portion 192 have different material compositions, such as different oxygen-to-silicon ratios, in accordance with some embodiments of the present disclosure. For example, the oxygen-to-silicon ratio of the liner portion 191 is greater than the oxygen-to-silicon ratio of the liner portion 192, in accordance with some embodiments of the present disclosure. The hardness of the liner portion 191 is less than the hardness of the liner portion 192, in accordance with some embodiments of the present disclosure. The refractive index of the liner portion 191 is less than the refractive index of the liner portion 192, in accordance with some embodiments of the present disclosure. In some embodiments, the via 260 penetrates the liner portion 192 and is separated from the liner portion 191. Therefore, the via 260 is more easily formed in the region R1, which increases the yield.

In some embodiments, the liner portion 191 is formed over the passivation layer 180. Afterwards, the liner portion 191 in the region is removed to form an opening, and the liner portion 192 is formed in the opening and in the region R1. The removal process includes a photolithography process and an etching process, such as a dry etching process, in accordance with some embodiments.

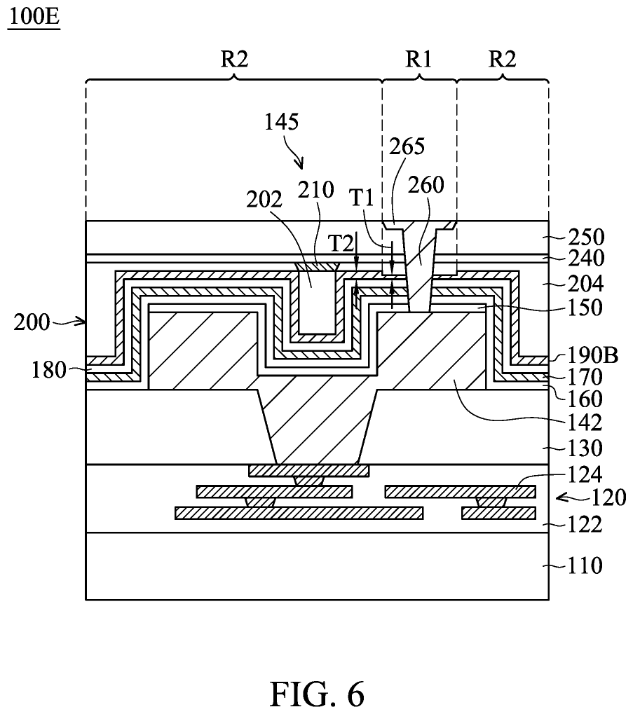

FIG. 6 is a schematic view of a semiconductor device structure 100E, in accordance with some embodiments of the present disclosure. Elements with similar reference numbers are not described again for simplicity. As shown in FIG. 6, the semiconductor device structure 100E has a region R1 adjacent to the via 260 and a region R2 spaced apart from the via 260 by the region R1, in accordance with some embodiments of the present disclosure.

The semiconductor device structure 100E has a liner 190B between the passivation layer 180 and the buffer layer 200, in accordance with some embodiments of the present disclosure. In some embodiments, the liner 190B has a thickness of T1 in region R1 and a thickness of T2 in region R2, and thickness T1 is less than thickness T2. As a result, it is easier to remove the liner 190B in the region R1 for forming the via 260 passing through the liner 190B, in accordance with some embodiments of the present disclosure. In some embodiments, the liner 190B is formed over the passivation layer 180, and then the liner 190B in the region R1 is partially removed to reduce the thickness of the liner 190B in the region R1. The removal process includes a photolithography process and an etching process, such as a dry etching process, in accordance with some embodiments.

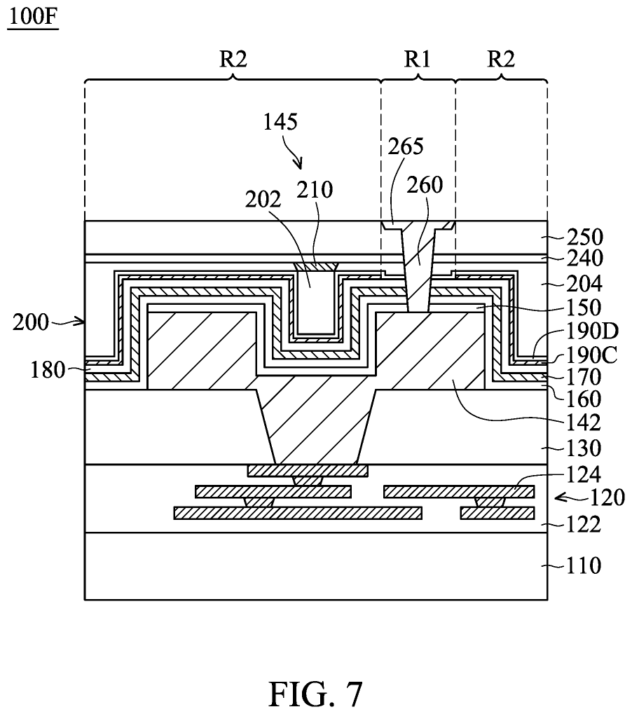

FIG. 7 is a schematic view of a semiconductor device structure 100F, in accordance with some embodiments of the present disclosure. Elements with similar reference numbers are not described again for simplicity. As shown in FIG. 7, the semiconductor device structure 100F has a region R1 adjacent to the via 260 and a region R2 spaced apart from the via 260 by region R1, in accordance with some embodiments of the present disclosure.

The semiconductor device structure 100F has a liner portion 190C over the passivation layer 180 and a liner portion 190D over the liner portion 190C, in accordance with some embodiments of the present disclosure. The liner portion 190D continuously extends across the semiconductor device structure 100F, such as continuously extends across the regions R1 and R2, in accordance with some embodiments. In some embodiments, the liner portion 190C is formed over the passivation layer 180, and then the liner portion 190C in the region R1 is partially removed to form an opening. Afterwards, the liner portion 190D is formed over the liner portion 190C and in the opening to make contact with the passivation layer 180 in the region R1, in accordance with some embodiments. Therefore, it is easier to form the via 260 in the region R1, which increases the yield.

In some embodiments, the liner portion 190C and the liner portion 190D have different material compositions. For example, the oxygen-to-silicon ratio of the liner portion 190C is greater than the oxygen-to-silicon ratio of the liner portion 190D, in accordance with some embodiments.

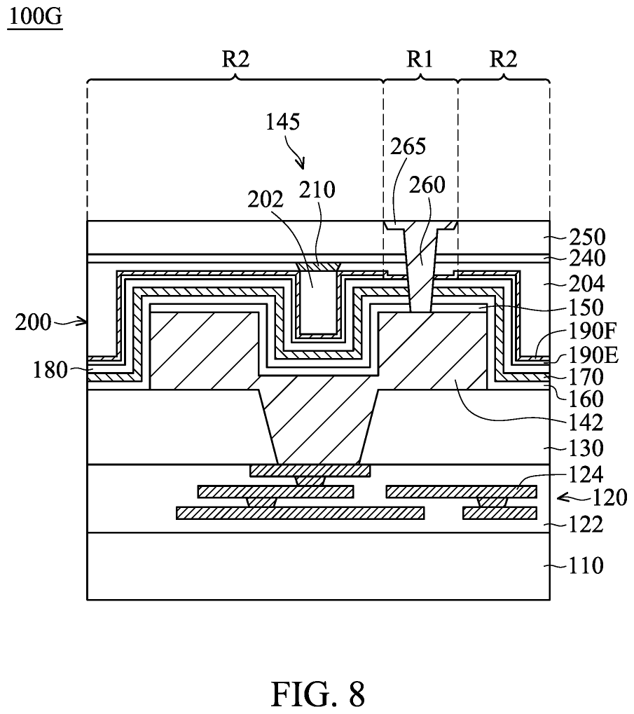

FIG. 8 is a schematic view of a semiconductor device structure 100G, in accordance with some embodiments of the present disclosure. Elements with similar reference numbers are not described again for simplicity. As shown in FIG. 8, the semiconductor device structure 100G has a region R1 adjacent to the via 260 and a region R2 spaced apart from the via 260 by the region R1, in accordance with some embodiments of the present disclosure.

The semiconductor device structure 100G has a liner portion 190E over the passivation layer 180 and a liner portion 190F over the liner portion 190E, in accordance with some embodiments of the present disclosure. The liner portion 190E continuously extends across the semiconductor device structure 100G, in accordance with some embodiments. In some embodiments, the liner portion 190E is formed over the passivation layer 180, and then the liner portion 190E in the region R1 is partially removed to form an opening. Afterwards, the liner portion 190F is formed over the liner portion 190F and in the opening to make contact with the passivation layer 180 in the region R1, in accordance with some embodiments. Therefore, it is easier to form the via 260 in the region R1, which increases the yield.

In some embodiments, the liner portion 190E and the liner portion 190F have different material compositions. For example, the oxygen-to-silicon ratio of the liner portion 190E is less than the oxygen-to-silicon ratio of the liner portion 190F, in accordance with some embodiments.

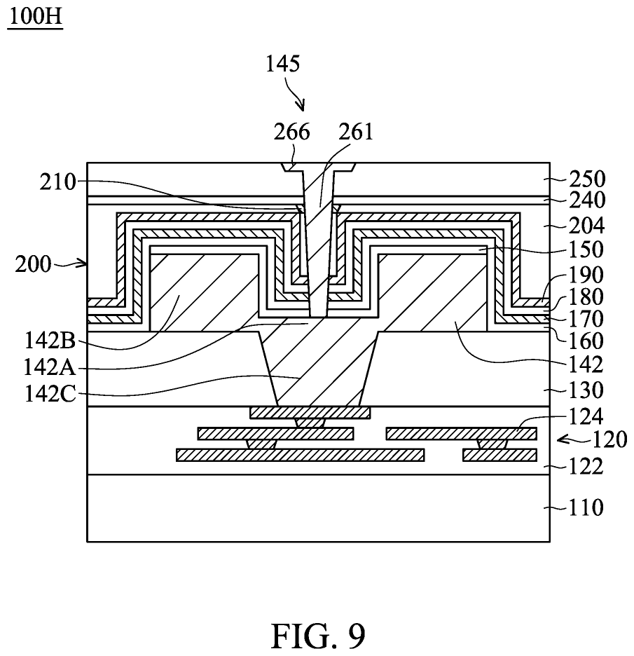

FIG. 9 is a schematic view of a semiconductor device structure 100H, in accordance with some embodiments of the present disclosure. Elements with similar reference numbers are not described again for simplicity. As shown in FIG. 9, a via 261 connects to the concave portion 142A and is surrounded by the surrounding portion 142B, in accordance with some embodiments of the present disclosure. In some embodiments, the via 261 penetrates the buffer layer 210 and is surrounded by the buffer layer 210.

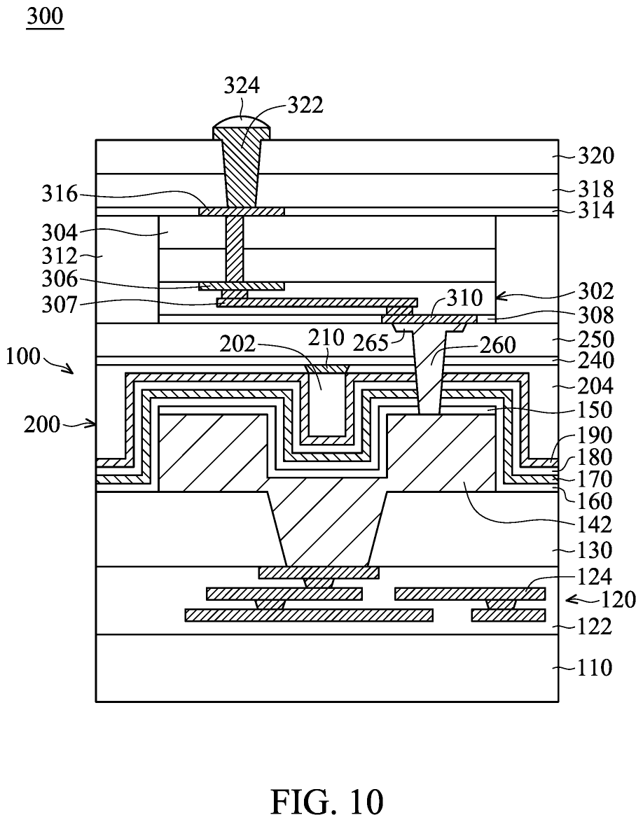

FIG. 10 shows a semiconductor package structure 300 formed with the semiconductor device structure 100, in accordance with some embodiments. As shown in FIG. 10, a device die 302 is disposed over the semiconductor device structure 100 in accordance with some embodiments.

In some embodiments, the device die 302 includes a substrate 304. The substrate 304 includes, for example, a semiconductor wafer (such as a silicon wafer) or a portion of a semiconductor wafer. In some embodiments, the substrate 304 is made of an elementary semiconductor material including silicon or germanium in a single crystal structure, a polycrystal structure, or an amorphous structure. In some other embodiments, the substrate 304 is made of a compound semiconductor, such as silicon carbide, gallium arsenide, gallium phosphide, indium phosphide, indium arsenide, an alloy semiconductor, such as SiGe or GaAsP, or a combination thereof. The substrate 304 may also include multi-layer semiconductors, semiconductor on insulator (SOI) (such as silicon on insulator or germanium on insulator), or a combination thereof.

In some embodiments, the device die 302 further includes integrated circuit devices 306, which may include active devices such as transistors and/or diodes, and passive devices such as capacitors, resistors, or the like are formed in the device die 302. Also, the device die 302 include interconnect structures 307 for connecting to the active devices and passive devices in device die 302. The interconnect structures 307 include metal lines and vias, in accordance with some embodiments.

The device die 302 includes a dielectric layer 308 and a bond pad 310 at the illustrated bottom surface of the device die 302, in accordance with some embodiments. The bottom surface of bond pad 310 is coplanar with the bottom surface of dielectric layer 308, in accordance with some embodiments.

The device die 302 may be bonded on the semiconductor device structure 100, in accordance with some embodiments. The bonding may be achieved through hybrid bonding. For example, the bond pad 310 is bonded to the bond pad 266 through metal-to-metal direct bonding. In accordance with some embodiments of the present disclosure, the metal-to-metal direct bonding includes a copper-to-copper direct bonding. Furthermore, the dielectric layer 308 is bonded to the insulating layer 250 through fusion bonding, in accordance with some embodiments.

After the bonding of the device die 302 to the semiconductor device structure 100, the device die 302 is encapsulated in encapsulating material (encapsulant) 312, in accordance with some embodiments. In some embodiments, the encapsulating material 312 may be a molding compound, a molding underfill, an epoxy, and/or a resin. In some embodiments, the encapsulating material 312 may include a base material and filler particles. In some embodiments, the base material may be a polymer, a resin, an epoxy, or the like. In some embodiments, the base material may be a carbon-based polymer. In some embodiments, the filler particles may be the particles of a dielectric material(s) such as SiO₂, Al₂O₃, silica, the compound of iron (Fe), the compound of sodium (Na), or the like, and may have spherical shapes, in accordance with some embodiments.

In some embodiments, a dielectric layer 314 is formed over the device die 302 and the encapsulating material 312. In some embodiments, the dielectric layer 314 includes low-k dielectric material having a k value lower than 3.8, and the k value may be lower than about 3.0, and lower than about 2.5, for example. In accordance with alternative embodiments, the dielectric layer 314 is formed of an oxide such as silicon oxide, a nitride such as silicon nitride, or the like. Conductive structure 316 is formed in the dielectric layer 314 and may include metal lines and metal pads, in accordance with some embodiments.

In some embodiments, a passivation layer 318 is formed over the dielectric layer 314. In some embodiments, the passivation layer 318 is a composite layer including a silicon oxide layer (not shown separately), and a silicon nitride layer (not shown separately) over the silicon oxide layer. The passivation layer 318 may also be formed of other non-porous dielectric materials such as Un-doped Silicate Glass (USG), silicon oxynitride, and/or the like, in accordance with some embodiments.

In some embodiments, an insulating layer 320 may be formed over the passivation layer 318. In some embodiments, the insulating layer 320 may include polyimide, polybenzoxazole (PBO), or the like.

In some embodiments, a conductive feature 322 is formed in the passivation layer 318 and the insulating layer 320 for connect to the conductive structure 316. In some embodiments, an electrical connector 324 is formed over the conductive feature 322. In some embodiments, the conductive feature 322 may include metal pads and metal lines. In some embodiments, the electrical connector 324 may include metal pillars, solder regions, or the like. Therefore, the semiconductor package structure 300 is formed, in accordance with some embodiments.

It should be noted that the semiconductor device structures shown in FIGS. 2-9 are also applicable for the semiconductor package structure 300, and these structure are not shown in the figures for simplicity.

In summary, semiconductor device structures and forming method thereof are provided in some embodiments of the present disclosure. The semiconductor device structure includes a liner with a function to suppress crack propagation, which increases the yield and reliability.

In some embodiments, a method for forming a semiconductor device structure is provided. The method includes forming an interconnect structure over a substrate. The method further includes forming a passivation layer over the interconnect structure. The method further includes forming a conductive structure over the passivation layer, wherein the conductive structure includes a surrounding portion over the passivation layer, and a concave portion surrounded by the surrounding portion. A height of the surrounding portion is greater than a height of the concave portion calculated from a top surface of the passivation layer. The method further includes forming a liner over the conductive structure, wherein an oxygen-to-silicon ratio of the liner is lower than about 1.8.

In some embodiments, a method for forming a semiconductor device structure is provided. The method includes forming an interconnect structure over a substrate. The method further includes forming a passivation layer over the interconnect structure. The method further includes patterning the passivation layer to form a through hole in the passivation layer. The method further includes forming a conductive structure in the through hole, wherein a first portion of the conductive structure overlaps the through hole and a second portion of the conductive structure covers a top surface of the passivation layer. The method further includes forming a dielectric layer over the conductive structure, wherein the dielectric layer extends into the first portion of the conductive structure. The method further includes forming a liner over the dielectric layer, wherein an oxygen-to-silicon ratio of the liner is in a range from about 1.5 to about 1.8. The method further includes forming a via penetrating the dielectric layer and the liner and landing on the second portion of the conductive structure.

In some embodiments, a semiconductor device structure is provided. The semiconductor device structure includes a substrate, an interconnect structure over the substrate, a passivation layer over the interconnect structure, a conductive structure over the passivation layer, a dielectric layer over the conductive structure, and a liner over the dielectric layer, wherein a refractive index of the liner is greater than about 1.6. The conductive structure includes a via portion in the passivation layer and electrically connected to the interconnect structure, a surrounding portion over the passivation layer, and a concave portion over the via portion and surrounded by the surrounding portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device struc202ture, comprising:
forming an interconnect structure over a substrate;
forming a passivation layer over the interconnect structure;
forming a conductive structure over the passivation layer, wherein the conductive structure comprises:
a surrounding portion over the passivation layer; and
a concave portion surrounded by the surrounding portion, wherein a height of the surrounding portion is greater than a height of the concave portion calculated from a top surface of the passivation layer; and
forming a liner over the conductive structure, wherein an oxygen-to-silicon ratio of the liner is lower than about 1.8.

2. The method as claimed in claim 1, further comprising:
forming a first buffer layer over the liner and surrounded by the surrounding portion;
forming a second buffer layer over the first buffer layer; and
partially removing the second buffer layer to expose the first buffer layer.

3. The method as claimed in claim 1, further comprising:
forming a first buffer layer over the liner and surrounded by the surrounding portion;
forming a second buffer layer over the first buffer layer; and
forming a nitride layer over the top surface of the second buffer layer, wherein the nitride layer and the first buffer layer are separated by the second buffer layer.

4. The method as claimed in claim 1, further comprising forming a first buffer layer over the liner and surrounded by the surrounding portion, wherein the first buffer layer comprises:
a first portion surrounded by the surrounding portion; and
a second portion over the surrounding portion, wherein the first portion is discontinuous from the second portion.

5. The method as claimed in claim 1, further comprising forming a first buffer layer over the liner and surrounded by the surrounding portion, wherein the first buffer layer comprises:
a first portion surrounded by the surrounding portion; and
a second portion over the surrounding portion, wherein the first portion and the second portion are continuously formed over the conductive structure.

6. The method as claimed in claim 5, wherein forming the first buffer layer comprises a High-Density Plasma Chemical Vapor Deposition (HDP-CVD) process.

7. The method as claimed in claim 1, wherein the conductive structure further comprises a via portion in the passivation layer and below the concave portion.

8. A method for forming a semiconductor device structure, comprising:
forming an interconnect structure over a substrate;
forming a passivation layer over the interconnect structure;
patterning the passivation layer to form a through hole in the passivation layer;
forming a conductive structure in the through hole, wherein a first portion of the conductive structure overlaps the through hole and a second portion of the conductive structure covers a top surface of the passivation layer;
forming a dielectric layer over the conductive structure, wherein the dielectric layer extends into the first portion of the conductive structure;
forming a liner over the dielectric layer, wherein an oxygen-to-silicon ratio of the liner is in a range from about 1.5 to about 1.8; and
forming a via penetrating the dielectric layer and the liner and landing on the second portion of the conductive structure.

9. The method as claimed in claim 8, wherein forming the liner comprises:
forming a first liner portion over the dielectric layer;
partially removing the first liner portion to form an opening; and
forming a second liner portion in the opening.

10. The method as claimed in claim 9, wherein oxygen-to-silicon ratios of the first liner portion and the second liner portion are different.

11. The method as claimed in claim 9, wherein the via penetrates the second liner portion and is separated from the first liner portion.

12. The method as claimed in claim 9, wherein the second liner portion covers the first liner portion.

13. The method as claimed in claim 8, wherein a thickness of the liner is between 50 and 150 nm.

14. A semiconductor device structure, comprising:
a substrate;
an interconnect structure over the substrate;
a passivation layer over the interconnect structure;
a conductive structure over the passivation layer, wherein the conductive structure comprises:
a via portion in the passivation layer and electrically connected to the interconnect structure;
a surrounding portion over the passivation layer; and
a concave portion over the via portion and surrounded by the surrounding portion;
a dielectric layer over the conductive structure; and
a liner over the dielectric layer, wherein a refractive index of the liner is greater than about 1.6.

15. The semiconductor device structure as claimed in claim 14, wherein a thickness of the liner in a first region is less than a thickness of the liner in a second region.

16. The semiconductor device structure as claimed in claim 15, wherein the liner comprises a first portion and a second portion, the first portion is in the second region, and the second portion is over the first portion and extends from the first region to the second region.

17. The semiconductor device structure as claimed in claim 14, wherein the refractive index of the liner in a first region is less than the refractive index of the liner in a second region, and the second region is surrounded by the first region.

18. The semiconductor device structure as claimed in claim 14, further comprising a via penetrating the dielectric layer and the liner, wherein the via connects to the surrounding portion.

19. The semiconductor device structure as claimed in claim 14, further comprising a via penetrating the dielectric layer and the liner, wherein the via connects to the concave portion.

20. The semiconductor device structure as claimed in claim 19, wherein the via is surrounded by the surrounding portion.
